(19) United States
(12) Patent Application Publication
(10) Pub. No.: US 2023/0411511 A1
(43) Pub. Date: Dec. 21, 2023

(54) POWER SEMICONDUCTOR DEVICE WITH DUAL SHIELD STRUCTURE IN SILICON CARBIDE AND MANUFACTURING METHOD THEREOF

(71) Applicant: TRinno Technology Co., Ltd., Seoul (KR)

(72) Inventors: Kwang Hoon OH, Seoul (KR); Soo Seong KIM, Seoul (KR); Chongman YUN, Seoul (KR)

(21) Appl. No.: 18/161,241

(22) Filed: Jan. 30, 2023

(30) Foreign Application Priority Data
Jun. 21, 2022 (KR) 10-2022-0075672

(51) Int. Cl. H01L 29/78; H01L 29/16; H01L 29/423; H01L 29/40; H01L 29/66

(52) U.S. Cl. CPC H01L 29/7813; H01L 29/1608; H01L 29/42376; H01L 29/42368; H01L 29/407; H01L 29/4236; H01L 29/66068

(57) ABSTRACT

Power semiconductor device with dual shield structure in silicon carbide and manufacturing method thereof disclosed. A silicon carbide power semiconductor device includes a substrate of a first conductivity type made of silicon carbide, a drift layer of the first conductivity type formed on an upper surface of the substrate with a relatively low impurity concentration compared to that of the substrate, a body region of a second conductivity type formed in an upper region of the drift layer, a different-widths gate trench, being etched to extend into the drift layer deeper than the body region, wherein an upper region of the different-widths gate trench is formed to be a wide-width region with a relatively wider width and a lower region of the different-widths gate trench is formed to be a narrow-width region with a relatively narrower width, wherein the wide-width region and the narrow-width region share a vertical center line so that the different-widths gate trench is formed in a boundary shape bent to have a stepped edge, a different-widths poly gate electrode filled in the different-widths gate trench so as to be insulated by a different-widths gate oxide and formed in a shape corresponding to the shape of the different-widths gate trench and a source region of the first conductivity type formed in an upper region of the body region in contact with sidewalls of the different-widths gate trench.

### FIELD

The present invention relates to a silicon carbide power semiconductor device having a dual shield structure and a manufacturing method thereof.

### RELATED ART

Power semiconductor devices such as IGBT(insulated gate bipolar transistor), power MOSFET(metal-oxide-semiconductor field effect transistor) and various types of thyristors, which are important elements in the field of power electronics, are being developed to meet various needs (e.g., high breakdown voltage, low conduction loss, high switching speed, low switching loss, etc.) in various industrial fields as well as automotive applications.

As a material for fabricating power semiconductor devices, since silicon carbide (SiC) has ten times higher maximum critical electric field and three times larger energy band gap than those of silicon (Si), it is advantageous to fabricate excellent power semiconductor devices having a high breakdown voltage (BV). For this reason, various researches on processes or structures are being conducted to implement a SiC power semiconductor device.

As an example of a power semiconductor device, a MOSFET typically includes a semiconductor body configured to conduct a load current along a load current path between two load terminals, and the load current path can be controlled by an insulated gate electrode. For example, upon receiving a corresponding control signal from a driver unit, the gate electrode may set the MOSFET to a conducting state or a blocking state.

In some cases, the gate electrode may be included in a trench of the MOSFET, which may be disposed to form, for example, a stripe configuration or cellular configuration within an active area composed of transistor cells (TCs).

However, in a MOSFET having a trench gate structure, an electric field crowding occurs at the bottom of the trench gate due to a high applied voltage to a drain in a reverse blocking mode.

If the electric field is continuously crowded at the bottom of the trench gate, a gate oxide is deteriorated to cause a gate short or an increase in gate leakage current, resulting in a decrease in reliability of the power semiconductor device.

In addition, the electric field crowding on the bottom of the trench gate has a problem in that the breakdown voltage of the power semiconductor device is not determined by the P/N junction or edge termination region of the active cell region, but is determined by the bottom of the gate trench.

The above-mentioned related art is technical information possessed by the inventor for derivation of the present invention or acquired in the derivation process of the present invention, and cannot necessarily be said to be a known technique disclosed to the general public prior to the filing of the present invention.

### SUMMARY

The present invention is for providing a SiC power semiconductor device with dual shield structure at a bottom of a trench gate and manufacturing method thereof, which may mitigate field crowding at the bottom of trench gate in reverse blocking mode in the SiC wide bandgap device to prevent degradation of gate oxide and secure high breakdown voltage thereby improving an operational reliability of the power semiconductor device.

Other objects of the present invention will be easily understood through the following description.

According to one aspect of the present invention, there is provided a silicon carbide power semiconductor device including a substrate of a first conductivity type made of silicon carbide, a drift layer of the first conductivity type formed on an upper surface of the substrate with a relatively low impurity concentration compared to that of the substrate, a body region of a second conductivity type formed in an upper region of the drift layer, a different-widths gate trench, being etched to extend into the drift layer deeper than the body region, wherein an upper region of the different-widths gate trench is formed to be a wide-width region with a relatively wider width and a lower region of the different-widths gate trench is formed to be a narrow-width region with a relatively narrower width, wherein the wide-width region and the narrow-width region share a vertical center line so that the different-widths gate trench is formed in a boundary shape bent to have a stepped edge, a different-widths poly gate electrode filled in the different-widths gate trench so as to be insulated by a different-widths gate oxide and formed in a shape corresponding to the shape of the different-widths gate trench and a source region of the first conductivity type formed in an upper region of the body region in contact with sidewalls of the different-widths gate trench.

In one embodiment, the different-widths gate oxide formed on the bottom of the narrow region of the different-widths gate trench may be formed to be twice or more thicker than a thickness of the different-widths gate oxide formed on the sidewall of the wide-width region.

In one embodiment, a shield region of the second conductivity type may be formed at both corner regions of the different-widths gate trench where the bottom of the wide-width region and sidewalls of the narrow-width region cross.

In one embodiment, the shield area may be formed to extend in a downward direction in contact with the bottom of the wide area as a whole, wherein the shield area may be in contact with sidewall of the narrow-width region to a same depth as a bottom of the different-widths poly gate electrode located in the narrow-width region in the different-widths gate trench.

In one embodiment, the body region and the shield region may formed together as an extension region of the second conductivity type in a state of being connected to each other at a same process and then separated from each other in an etching process in which the drift layer is etched to form the wide-width trench for forming the wide-width region.

In one embodiment, the body region and the shield region may be formed with the same impurity concentration.

In one embodiment, a thickness of the shield region may be set equal to a depth at which the body region is formed.

In one embodiment, the silicon carbide power semiconductor device may further include a contact region of the second conductivity type formed in the upper region of the body region to contact the source region, wherein the contact region may be bonded to the source metal layer with a recess-etched contact structure.

According to another aspect of the present invention, there is provided a method of fabricating a silicon carbide power semiconductor device including forming, on an upper surface of a silicon carbide substrate of a first conductivity type, a drift layer of the first conductivity type with an impurity concentration relatively lower than that of the substrate, forming a source region of the first conductivity type in an upper region of the drift layer, etching a narrow-width trench to form a narrow-width region having a predetermined width w1 through the source region to a predetermined depth d1 reaching the drift layer, forming a lower oxide region having a thickness corresponding to a difference between the depth d1 and a depth d2 in the narrow-width region of the narrow-width trench, forming an extension region of a second conductivity type extending in a lateral direction at a predetermined depth d3 and further extending along a sidewall of the narrow-width trench with a predetermined width w2 to the depth d2 of an upper surface of the lower oxide region on both sides of the narrow-width trench by vertically implanting ions of the second conductivity type on a top of the drift layer except for the narrow-width trench and obliquely implanting ions of the second conductivity type into the narrow-width trench through the sidewall of the narrow-width trench, and forming a different-widths gate trench having a wide-width region and the narrow-width region by etching a wide-width trench that shares a vertical center line with the narrow-width trench and forms the wide-width region with a predetermined width w3 for removing the extension region extending along the sidewall of the narrow-width trench to a depth d4, thereby separating the extension region into a body region in contact with the sidewall of the wide-width trench and a shield region in contact with a bottom of the wide-width trench and sidewall of the narrow-width trench, wherein depths d1, d2, d3 and d4 have a relationship of d1>d2>d4>d3.

In one embodiment, a method of fabricating a silicon carbide power semiconductor device may further include forming an upper oxide region connected to the lower oxide region on an inner wall of the different-widths gate trench in which the lower oxide region is formed and forming a different-widths poly gate electrode being insulated by a different-widths gate oxide consisting of the connected lower oxide region and upper oxide region in the inside of the different-widths gate trench, wherein the different-widths gate oxide formed at the bottom of the narrow-width region of the different-widths gate trench is formed to be twice or more thicker than the different-widths gate oxide formed on the sidewall of the wide-width region.

In one embodiment, a bottom of the shield region may be located at the same depth as a bottom of the different-widths poly gate electrode located in the narrow-width region in the different-widths gate trench.

Aspects, features, advantages other than above described will be apparent from the following drawings, claims and detailed description.

According to embodiments of the present invention, it may be advantageous to improve an operational reliability of the power semiconductor device by mitigating field crowding at the bottom of trench gate in reverse blocking mode in the SiC wide bandgap device to prevent degradation of gate oxide and secure high breakdown voltage thereby improving.

### BRIEF DESCRIPTION OF ACCOMPANYING DRAWINGS

FIG. 1 is a cross-sectional view of a conventional trench gate type SiC MOSFET;

FIG. 2A and FIG. 2B are cross-sectional views of a conventional trench gate type SiC MOSFET to which a field crowding prevention structure is applied;

FIG. 3 exemplarily illustrates a cross-sectional view of a trench gate type SiC MOSFET according to one embodiment of the present invention;

FIG. 4 exemplarily illustrates a shape of a poly gate electrode according to one embodiment of the present invention;

FIGS. 5, 6 and 7 exemplarily illustrate a manufacturing process of a trench gate type SiC MOSFET according to one embodiment of the present invention; and

FIG. 8 exemplarily illustrates a cross-sectional view of a trench gate type SiC MOSFET according to another embodiment of the present invention.

### DESCRIPTION OF EMBODIMENTS

The invention can be modified in various forms and specific embodiments will be described and shown below. However, the embodiments are not intended to limit the invention, but it should be understood that the invention includes all the modifications, equivalents, and replacements belonging to the concept and the technical scope of the invention. In describing the present invention, if it is determined that a detailed description of a related known technology may obscure the gist of the present invention, the detailed description thereof will be omitted.

Terms such as first, second, etc., may be used to refer to various elements, but, these elements should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

Relative terms, such as “below” or “above” or “upper” or “lower” or “horizontal” or “lateral” or “vertical” may be used herein to describe-one element, layer or region's relationship to another elements, layers or regions as illustrated in the Figures. It will be understood that relative terms are intended to encompass different orientations of the device in addition to the orientation depicted in the Figures.

Hereinafter, an embodiment of the present invention will be described in detail with reference to the accompanying drawings. However, in the following description, power MOSFET will be mainly described, but it should be understood that the technical concept of the present invention may be applied and expanded to various types of semiconductor devices such as IGBT in the same or similar manner.

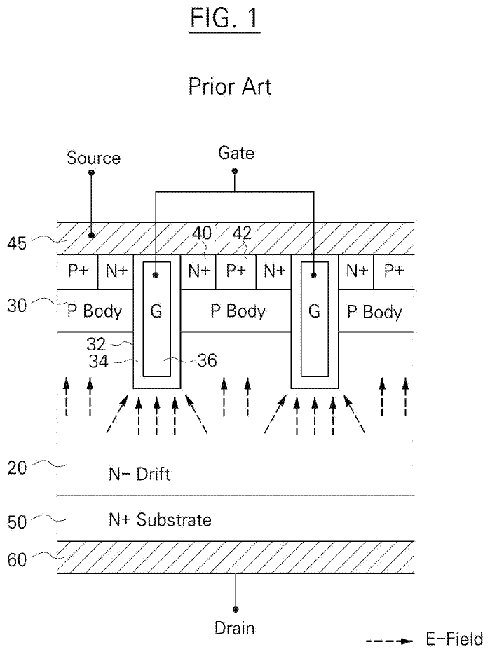

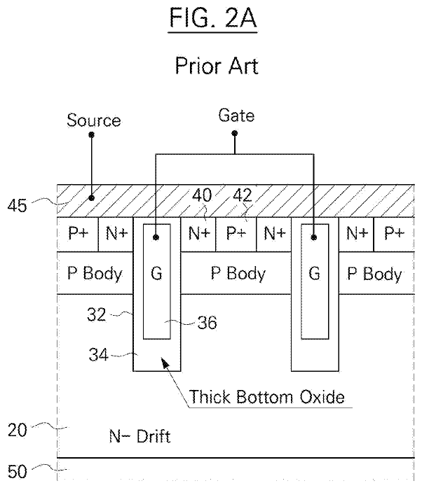

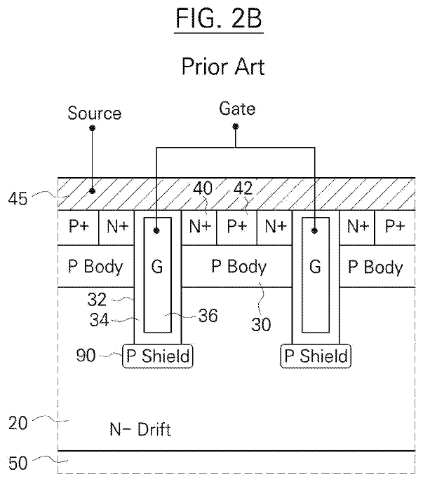

FIG. 1 is a cross-sectional view of a conventional trench gate type SiC MOSFET, and FIGS. 2A and 2B are cross-sectional views of a conventional trench gate type SiC MOSFET to which a field crowding prevention structure is applied.

Referring to FIG. 1, a trench gate type SiC MOSFET (hereinafter, abbreviated as ‘SiC MOSFET’) includes an N+conductivity type substrate 50, an N−conductivity type drift region 20, a P conductivity type body region 30, a gate trench 32, a gate oxide 34, a poly gate electrode 36, an N+conductivity type source region 40, a P+conductivity type contact region 42, a source metal layer 45, and a drain metal layer 60.

The SiC MOSFET is fabricated with a semiconductor substrate consisting of the N+conductivity type substrate 50 doped with a high concentration of impurity and the N−conductivity type drift layer 20 formed with a relatively lower concentration of impurity than that of the substrate 50.

The P conductivity type body region 30 is formed in the upper region of the drift layer 20, and the N+conductivity type source region 40 and the P+conductivity type contact region 42 are formed to be in contact with each other in the upper region of the body region 30 (namely, on the top surface of the semiconductor substrate).

The gate trench 32, by being etched to a predetermined depth in the drift layer 20, penetrates the source region 40 and extends deeper than the body region 30. The gate oxide 34 is formed on the inner wall of the gate trench 32. The poly gate electrode 36 is buried in the gate trench 32 to be insulated from the body region 30, the source region 40, and the source metal layer 45 by the gate oxide 34.

The source metal layer 45 is formed on the upper surface of the semiconductor substrate, and the drain metal layer 60 is formed on the lower surface of the semiconductor substrate.

As shown in FIG. 1, in the blocking mode of the SiC MOSFET, the field crowding occurs on the bottom of the gate trench 32.

When a breakdown voltage is applied, the critical electric field of SiC is about ten times higher than that of Si, and theoretically, an electric field of about 7.5 MV/cm is concentrated in the gate oxide. During repetitive blocking mode operations, there are problems that the gate oxide 34 is deteriorated to cause the gate short or increase of gate leakage current, and the breakdown voltage of the SiC MOSFET to be determined at the bottom of the gate trench 32.

In order to solve this problem, as illustrated in FIG. 2A, a field crowding prevention structure is suggested in which the gate oxide 34 formed at the bottom of the gate trench 32 where the electric field is concentrated is formed thickly to mitigate the field crowding.

To this end, first, the gate trench 32 is etched in the semiconductor substrate, and a relatively thick gate oxide 34 is formed on the inner wall of the gate trench 32. Thereafter, a process of etching the thick gate oxide 34 in the remaining area except for the bottom area of the gate trench 32 and forming the remaining area with the gate oxide 34 having an intended thickness at the trench interface is performed.

Alternatively, as illustrated in FIG. 2B, another field crowding prevention structure to mitigate the field crowding on the bottom of the trench 32 is suggested in which after etching the gate trench 32 in the semiconductor substrate, P conductivity type impurities are additionally implanted into the bottom surface of the gate trench 32 to form a P conductivity type floating region 90 around the bottom of the gate trench 32.

The floating region 90 around the bottom of the gate trench 32 is formed to be separated from the body region 30 by the drift region 20, and also from other floating regions 90 formed at the adjacent gate trenches 32 by the drift region 20.

The field crowding prevention structure shown in FIG. 2A, in which the gate oxide 34 at the bottom of the gate trench 32 is thickly formed, can be an effective electric field shielding in the vertical direction.

However, there is a problem that the oblique electric field being concentrated at the junction between the gate oxide 34 formed thickly at the bottom of the gate trench 32 and the gate oxide 34 formed relatively thin at the interface of the gate trench 32 makes the junction vulnerable.

The field crowding prevention structure in which the floating region 90 is formed around the bottom of the gate trench 32 as shown in FIG. 2B may be effective in terms of mitigating the field crowding.

However, since the width of the P conductivity type floating region 90 is formed relatively wider than the width of the gate trench 32, there is a problem in that the on-resistance is increased by acting as resistance in a current path in the channel direction.

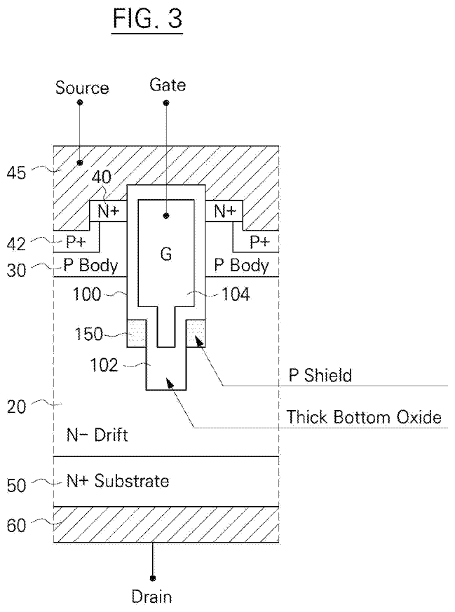

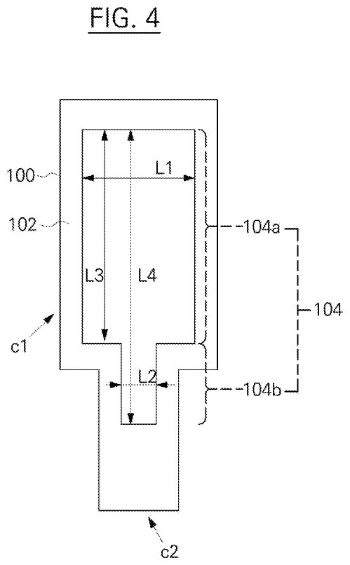

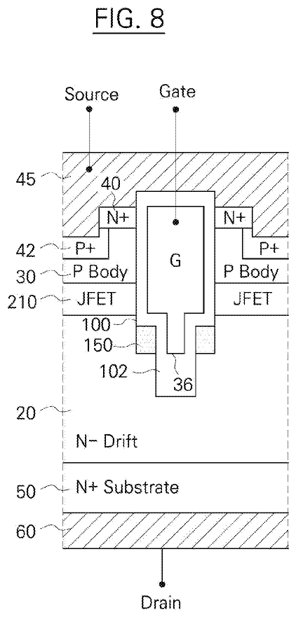

FIG. 3 exemplarily illustrates a cross-sectional view of a trench gate type SiC MOSFET according to one embodiment of the present invention, and FIG. 4 exemplarily illustrates a shape of a poly gate electrode according to one embodiment of the present invention. 5, 6 and 7 exemplarily illustrate a manufacturing process of a trench gate type SiC MOSFET according to one embodiment of the present invention, and FIG. 8 exemplarily illustrates a cross-sectional view of a trench gate type SiC MOSFET according to another embodiment of the present invention.

Referring to FIG. 3, the SiC MOSFET may include a substrate 50 of N+conductivity type, a drift region 20 of N−conductivity type, a body region 30 of P conductivity type, a different-widths gate trench 100, a different-widths gate oxide 102, a different-widths poly gate electrode 104, a shield region 150 of P conductivity type, a source region 40 of N+conductivity type, a contact region 42 of P+conductivity type, a source metal layer 45, and a drain metal layer 60.

The SiC MOSFET is fabricated with a semiconductor substrate consisting of the N+conductivity type substrate 50 doped with a high concentration of impurity and the drift layer 20 of N−conductivity type formed with a relatively lower concentration of impurity than that of the substrate 50.

The body region 30 of P conductivity type is formed in the upper region of the drift layer 20, and the source region 40 of N+conductivity type and the contact region 42 of P+conductivity type are formed to be in contact with each other in the upper region of the body region 30 (namely, on the top surface of the semiconductor substrate).

The different-widths gate trench 100, by being etched relatively deeper than the body region 30 to a predetermined depth in the drift layer 20, may penetrate the source region 40 and extends deeper than the body region 30. The different-widths gate oxide 102 may be formed on the inner wall of the different-widths gate trench 100. The different-widths poly gate electrode 104 may be buried in the different-widths gate trench 100 to be insulated from the body region 30, the source region 40, and the source metal layer 45 by the different-widths gate oxide 102.

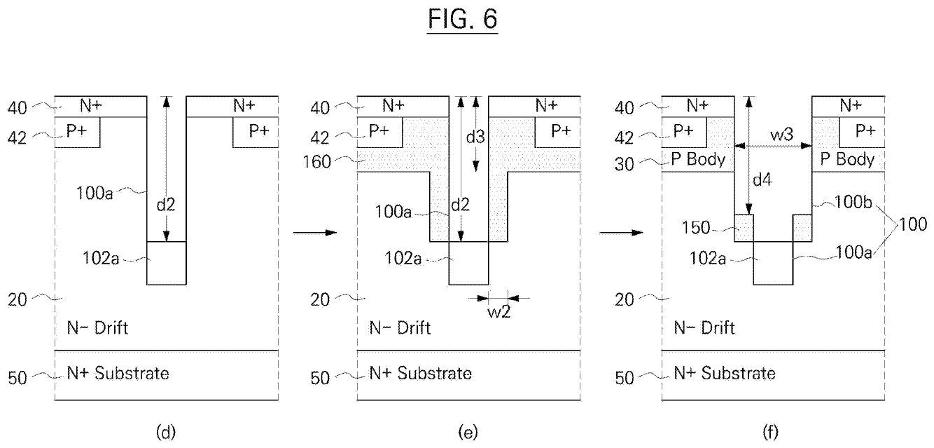

The different-widths gate trench 100 may be formed by etching a narrow-width trench 100a penetrating the source region 40 and extending to the drift layer 20 relatively deeper than the body region 30 to form a narrow-width region (see (c) of FIG. and then further etching a wide-width trench 100b by widening an upper region of the narrow-width trench 100a to form a wide-width region (see (f) of FIG. 6). Namely, the different-widths gate trench 100 may be formed, for example in T shape, of which upper region is formed to be the wide-width region with relatively wide width and lower region is formed to be the narrow-width region with relatively narrow width.

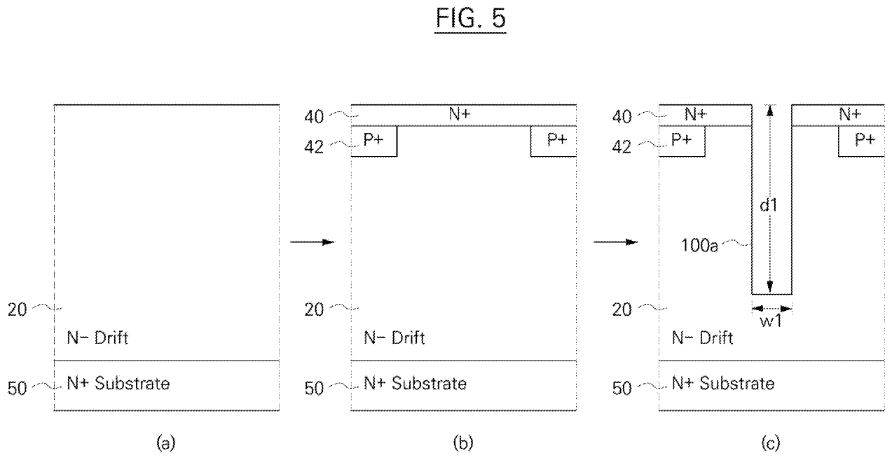

As shown in (c) of FIG. 5, the narrow-width trench 100a may be formed by being etched through the source region 40 to reach the drift layer 20, and may have a width of w1 and a depth of d1. In contrast, as shown in (f) of FIG. 6, the wide-width trench 100b may be formed to have a width w3 to a depth d4 corresponding to the upper region of the narrow-width trench 100a, so that the width down to the depth d4 of the entire section of the narrow-width trench 100a may be extended. Where, d1 is deeper than d4 and w3 is wider than w1, and vertical center lines of the narrow-width trench 100a and the wide-width trench 100b may be aligned on the same line.

In this way, by forming the narrow-width trench 100a and then forming the wide-width trench 100b so that the upper region of the narrow-width trench 100a is further widened, the double-widths gate trench 100 may be formed in a shape in which an upper region (namely, the region down to depth d4) has a relatively wider width than a lower region (namely, the region between depth d4 and depth d1).

The different-widths gate trench 100 may be formed in a boundary shape bent to have a stepped edge, so that the sidewalls of the wide-width trench 100b and the narrow-width trench 100a are not continuous in a consistent shape.

In FIG. 3 and other FIGS., when viewed in a cross-sectional direction, the upper region and the lower region of the different-widths gate trench 100 are illustrated as having a rectangular shape, but the shape of the upper region and the lower region may vary, for example, by etching at least one of the narrow-width trench 100a and the wide-width trench 100b at an angle.

As illustrated in FIG. 4, a lower oxide region 102a (see (d) of FIG. 6) on the bottom c2 of the different-widths gate trench 100 may be formed to be relatively thicker than the oxide on the sidewall c1 of the different-widths gate trench 100.

For example, if the different-widths gate oxide 102 is formed to a thickness of 500 angstroms or less on the sidewall c1 of the different-widths gate trench 100, the different-widths gate oxide 102 may be formed at the bottom c2 of the different-widths gate trench 100 by a thickness of twice or more. For example, the different-widths gate oxide 102 may be formed to a thickness of 3,000 to 5,000 angstroms (about 6 to times) at the bottom c2 of the narrow region of the different-widths gate trench 100.

The inside of the different-widths gate trench 100 may be filled with the different-widths poly gate electrode 104 to be insulated by the different-widths gate oxide 102.

By forming the different-widths gate oxide 102 on the inner wall of the different-widths gate trench 100, in which the lower oxide region 102a is already formed, and then performing a poly deposition process, the inside of the two-width gate trench 100 may be filled with the two-width poly gate electrode 104 being insulated.

As shown in FIG. 4, the different-widths poly gate electrode 104 filled in the inside of the different-widths gate trench 100 also corresponds to the shape of the different-widths gate trench 100, namely, the upper first sub-region 104a may be formed to be relatively wider than the lower second sub-region 104b.

That is, the width L1 of the first sub-region 104a of the different-widths poly gate electrode 104 may be set relatively larger than the width L2 of the second sub-region 104b, and in order to form the second sub-region 104b, the thickness L3 of the first sub-region 104a may be set to be relatively small compared to the total thickness L4 of the different-widths poly gate electrode 104.

In order to correspond to the different-widths gate trench 100, the different-widths poly gate electrode 104 may also be formed in the boundary shape bent to have the stepped edge. In this case, the outer surfaces of the wide-width first sub-region 104a and the narrow-width second sub-region 104b are not continuous in a mutually consistent shape, such as a T-shape.

When viewed in a cross-sectional direction, each of the first sub-region 104a and the second sub-region 104b of the different-widths poly gate electrode 104 may have a rectangular shape, but it should be understood that these may be formed in any shapes such as a trapezoidal shape corresponding to the shape of the different-widths gate trench 100.

The shield region 150 of the P conductivity type may be formed in both corner regions of the double-width gate trench 100 which forms the bent boundary so that the wide-width trench 100b and the narrow-width trench 100a are connected to each other. That is, the shield region 150 may be formed at both corner regions of the different-widths gate trench 100 formed by the bottom of the wide-width trench 100b and the sidewall of the narrow-width trench 100a.

The shield region 150 may be formed in a shape in which it entirely contacts the bottom of the wide-width trench 100b and continuously contacts the sidewall of the narrow-width trench 100a down to the depth of the bottom of the different-widths poly gate electrode 104. The shield region 150 may be formed to be relatively wider and relatively thicker than the thickness of the different-widths gate oxide 102 formed on the sidewall c1 of the different-widths gate trench 100 (see FIG. 4).

As such, the shield region 150 is formed at both corner regions of the different-widths gate trench 100 corresponding to the entire bottom of the wide-width trench 100b, excluding the portion to which the narrow-width trench 100a is connected, so that the field crowding on the bottom of the wide-width trench 100b for forming the different-widths gate trench 100 may be mitigated.

That is, the field crowding prevention structure on the bottom of the different-widths gate trench 100 according to the present embodiment may include the lower oxide region 102a of the different-widths gate oxide 102 thickly formed on the inner wall of the bottom of the narrow-width trench 100a and shield regions 150 formed under the bottom of the wide-width trench 100b on both sides of the narrow-width trench 100a. Namely, the field crowding prevention structure is a dual shield structure.

With the aid of the dual shield structure, the field crowding on the bottom of the trench gate may be mitigated to secure a high breakdown voltage in SiC and wide bandgap devices, thereby improving operational reliability of the power semiconductor device.

The source metal layer 45 may be formed on the upper surface of the semiconductor substrate, and the drain metal layer 60 may be formed on the lower surface of the semiconductor substrate.

As shown in FIG. 3, in order to prevent parasitic bipolar turn-on to enhance the ruggedness characteristics of the SiC MOSFET, the contact region 42 in contact with the source region 40 may have a recess-etched contact structure to be contacted to the source metal layer 45.

As another embodiment of the present invention, as shown in FIG. 8, a JFET region 210 of N conductivity type, which is a low-resistance region, may be further formed to a predetermined thickness under the body region 30 to reduce on-resistance.

Hereinafter, with reference to FIGS. 5 to 7, a manufacturing method of the SiC MOSFET according to the present embodiment will be briefly described.

Referring to FIG. 5, a semiconductor substrate consisting of the N+conductivity type substrate 50 doped with a high concentration of impurity and the drift layer 20 of N-conductivity type formed with a relatively lower concentration of impurity than that of the substrate 50 is formed (see (a) of FIG. 5).

Subsequently, P conductivity type ions and N conductivity type ions are implanted into the upper region of the drift layer 20 to form a source region 40 and a contact region 42 in predetermined regions, respectively (see (b) of FIG. 5).

For example, when viewed in a cross-sectional direction, the source region 40 may be formed to be continuous in the upper region of the drift layer 20 in the horizontal direction, and the contact region 42 may be formed to be adjacent to the lower region of the source region 40 and to be spaced apart from each other in the upper region of the drift layer 20 in the horizontal direction. An additional mask (not shown) may be used to form the contact areas 42 spaced apart from each other in the horizontal direction.

Next, a narrow-width trench 100a expending through the source region 40 into the drift layer 20 is etched at a predetermined depth d1 and width w1 (see (c) of FIG. 5). A vertical center line of the narrow-width trench 100a may coincide with an intermediate position between the contact regions 42 spaced apart from each other.

Next, after a different-widths gate oxide 102 is formed to fill the inside of the narrow-width trench 100a, the different-widths gate oxide 102 filling the inside of the narrow-width trench 100a is etched to a predetermined depth d2 so as to remain a lower oxide region 102a having a predetermined thickness (namely, d1-d2) at the bottom of the narrow-width trench 100a (see (d) of FIG. 6).

Subsequently, P conductivity type ions are vertically implanted on the top of the semiconductor substrate except for the narrow-width trench 100a, and are obliquely implanted into the narrow-width trench 100a through the sidewall of the narrow-width trench 100a, thereby forming an extension region 160 that extends in the lateral direction at a predetermined depth d3, but extends along the sidewalls of the narrow-width trench 100a with a predetermined width w2 to a depth d2 of the upper surface of the lower oxide region 120a on both sides of the narrow-width trench 100a. In order to activate the implanted P conductivity type ions and form the extension region 160, high-temperature annealing at a predetermined temperature may be performed.

Next, a wide-width trench 100b having a predetermined width w3 sharing the vertical center line of the narrow-width trench 100a is formed in an upper region of the narrow-width trench 100a corresponding to a predetermined depth d4 (see (f) of FIG. 6).

The wide-width trench 100b is etched to remove the extension region extending along the sidewall of the narrow-width trench 100a to a predetermined depth d2 with a predetermined width w2, thereby separating the extension region 160 into a body region on both sides of the wide-width trench 100b and a shield region 150 with a predetermined thickness (namely, d2-d4) at corners consisting of the bottom of the wide-width trench 100b and the sidewall of the narrow-width trench 100a. For example, the thickness d2-d4 of the shield region 150 may be set equal to the depth d3 at which the body region 30 is formed.

Since being formed in the upper region of the narrow-width trench 100a in order to remove the extension region 160 formed along both sides of the narrow-width trench 100a with width w2 to the predetermined depth d4, the width w3 of the wide-width trench 100b may be w1+(2×w2).

The different-widths gate trench 100, in which the wide-width trench 100b is located in the upper region, shares a vertical center line, and the narrow-width trench 100a is connected to the lower part, is formed to have a sidewall shape such as a T-shape to have stepped edges.

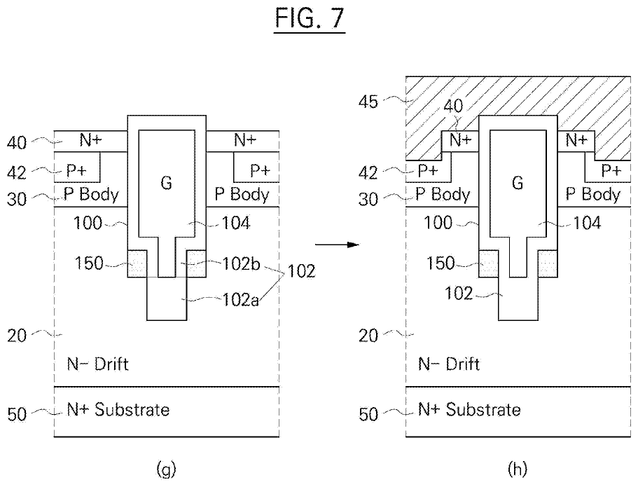

Subsequently, a different-widths gate oxide 102 is formed by forming an upper oxide region 102b connected to the lower oxide region 102a on the inner wall of the different-widths gate trench 100 having the lower oxide region 102a at the bottom, and the inside of the different-widths gate trench 100 is filled with a different-widths poly gate electrode 104 to be insulated from the body region 30 and the source region 40 (see (g) of FIG. 7). The bottom of the different-widths poly gate electrode 104 may be formed at the same depth as the bottom of the shield region 150.

The different-widths poly gate electrode 104 filled in the different-widths gate trench 100 also corresponds to the shape of the different-widths gate trench 100, so that the upper first sub-region 104a (see FIG. 4) may be formed to have a relatively wider width than the lower second sub-region 104b(see FIG. 4).

Subsequently, the contact region 42 in contact with the source region 40 is bonded to the source metal layer 45 formed on the upper surface of the semiconductor substrate with a recess-etched contact structure (see (h) of FIG. 7). The drain metal layer 60 may be formed on the lower surface of the semiconductor substrate (see FIG. 3).

Up to now, the power semiconductor device has been described using the power MOSFET as an example, but it should be understood that the technical concept of the present invention may be applied and expanded to various types of power semiconductor devices such as IGBT in the same or similar manner.

Although the above has been described with reference to the embodiments of the present invention, those of ordinary skill in the art can variously modify the present invention without departing from the spirit and scope of the present invention described in the claims below.

What is claimed is:

1. A silicon carbide power semiconductor device, comprising:
a substrate of a first conductivity type made of silicon carbide;
a drift layer of the first conductivity type formed on an upper surface of the substrate with a relatively low impurity concentration compared to that of the substrate;
a body region of a second conductivity type formed in an upper region of the drift layer;
a different-widths gate trench, being etched to extend into the drift layer deeper than the body region, wherein an upper region of the different-widths gate trench is formed to be a wide-width region with a relatively wider width and a lower region of the different-widths gate trench is formed to be a narrow-width region with a relatively narrower width, wherein the wide-width region and the narrow-width region share a vertical center line so that the different-widths gate trench is formed in a boundary shape bent to have a stepped edge;
a different-widths poly gate electrode filled in the different-widths gate trench so as to be insulated by a different-widths gate oxide and formed in a shape corresponding to the shape of the different-widths gate trench; and
a source region of the first conductivity type formed in an upper region of the body region in contact with sidewalls of the different-widths gate trench,
wherein the different-widths gate oxide formed on the bottom of the narrow region of the different-widths gate trench is formed to be twice or more thicker than a thickness of the different-widths gate oxide formed on the sidewall of the wide-width region,
wherein a shield region of the second conductivity type is formed at both corner regions of the different-widths gate trench where the bottom of the wide-width region and sidewalls of the narrow-width region cross.

2. The silicon carbide power semiconductor device of claim 1, wherein the shield area is formed to extend in a downward direction in contact with the bottom of the wide area as a whole,
wherein the shield area is in contact with sidewall of the narrow-width region to a same depth as a bottom of the different-widths poly gate electrode located in the narrow-width region in the different-widths gate trench.

3. The silicon carbide power semiconductor device of claim 1, wherein the body region and the shield region are formed together as an extension region of the second conductivity type in a state of being connected to each other at a same process and then separated from each other in an etching process in which the drift layer is etched to form the wide-width trench for forming the wide-width region.

4. The silicon carbide power semiconductor device of claim 1, wherein the body region and the shield region are formed with the same impurity concentration.

5. The silicon carbide power semiconductor device of claim 2, wherein a thickness of the shield region is set equal to a depth at which the body region is formed.

6. The silicon carbide power semiconductor device of claim 1 further comprising a contact region of the second conductivity type formed in the upper region of the body region to contact the source region,
wherein the contact region is bonded to the source metal layer with a recess-etched contact structure.

7. A method of fabricating a silicon carbide power semiconductor device, comprising:
forming, on an upper surface of a silicon carbide substrate of a first conductivity type, a drift layer of the first conductivity type with an impurity concentration relatively lower than that of the substrate;
forming a source region of the first conductivity type in an upper region of the drift layer;
etching a narrow-width trench to form a narrow-width region having a predetermined width w1 through the source region to a predetermined depth d1 reaching the drift layer;
forming a lower oxide region having a thickness corresponding to a difference between the depth d1 and a depth d2 in the narrow-width region of the narrow-width trench;
forming an extension region of a second conductivity type extending in a lateral direction at a predetermined depth d3 and further extending along a sidewall of the narrow-width trench with a predetermined width w2 to the depth d2 of an upper surface of the lower oxide region on both sides of the narrow-width trench by vertically implanting ions of the second conductivity type on a top of the drift layer except for the narrow-width trench and obliquely implanting ions of the second conductivity type into the narrow-width trench through the sidewall of the narrow-width trench; and
forming a different-widths gate trench having a wide-width region and the narrow-width region by etching a wide-width trench that shares a vertical center line with the narrow-width trench and forms the wide-width region with a predetermined width w3 for removing the extension region extending along the sidewall of the narrow-width trench to a depth d4, thereby separating the extension region into a body region in contact with the sidewall of the wide-width trench and a shield region in contact with a bottom of the wide-width trench and sidewall of the narrow-width trench,
wherein depths d1, d2, d3 and d4 have a relationship of d1>d2>d4>d3.

8. The method of claim 7 further comprising forming an upper oxide region connected to the lower oxide region on an inner wall of the different-widths gate trench in which the lower oxide region is formed and forming a different-widths poly gate electrode being insulated by a different-widths gate oxide consisting of the connected lower oxide region and upper oxide region in the inside of the different-widths gate trench,
wherein the different-widths gate oxide formed at the bottom of the narrow-width region of the different-widths gate trench is formed to be twice or more thicker than the different-widths gate oxide formed on the sidewall of the wide-width region.

9. The method of claim 8, wherein a bottom of the shield region is located at the same depth as a bottom of the different-widths poly gate electrode located in the narrow-width region in the different-widths gate trench.
